(19) United States
(12) Patent Application Publication
(10) Pub. No.: US 2015/0357298 A1
(43) Pub. Date: Dec. 10, 2015

(54) SEMICONDUCTOR CHIP, SEMICONDUCTOR PACKAGE HAVING THE SAME AND METHOD OF MANUFACTURING THE SAME

(71) Applicant: Samsung Electronics Co., Ltd., Suwon-si (KR)

(72) Inventors: Jae-Gwon JANG, Hwaseong-si (KR); Jong-Ho LEE, Hwaseong-si (KR); Ae-Nee JANG, Seoul (KR)

(21) Appl. No.: 14/637,545

(22) Filed: Mar. 4, 2015

(30) Foreign Application Priority Data
Jun. 10, 2014 (KR) 10-2014-0070164

(51) Int. Cl. H01L 23/00; H01L 25/065; H01L 25/00

(52) U.S. Cl. CPC H01L 24/09; H01L 25/50; H01L 24/03; H01L 25/0657; H01L 2224/0233

(57) ABSTRACT

A semiconductor chip includes a semiconductor chip die having a first surface and a second surface facing the first surface, a connection pad on the first surface of the semiconductor chip die, and a redistribution pad arranged on the first surface of the semiconductor chip die and electrically connected to the connection pad and including an end portion having a concave-convex structure and extended to a lateral surface of the semiconductor chip die.

### PRIORITY STATEMENT

This application claims priority under 35 U.S.C. §119 to Korean Patent Application No. 10-2014-0070164, filed on Jun. 10, 2014 in the Korean Intellectual Property Office (KIPO), the contents of which are herein incorporated by reference in their entirety.

### BACKGROUND

1. Field

Example embodiments relate to a semiconductor chip, a semiconductor package having the same, and/or a method of manufacturing the same. More particularly, example embodiments relate to stacked semiconductor chips, a semiconductor package having the same, and/or a method of manufacturing the same.

2. Description of the Related Art

High integration and single packaging technologies for semiconductor chips used in a semiconductor product may be required. The packaging technologies for improving mechanical and electrical reliability and minimizing the packaging size are becoming more and more important. Particularly, in order to manufacture a semiconductor package, stacking a plurality of semiconductor chips can realize chip capacity increase, low power, higher transmission rate, and higher efficiency of a semiconductor chip.

### SUMMARY

Some example embodiments relate to a semiconductor package having a highly reliable electrical connection.

Some example embodiments relate to a method of manufacturing a semiconductor package having a highly reliable electrical connection.

According to example embodiments, a semiconductor chip includes a semiconductor chip die having a first surface and a second surface facing the first surface, a connection pad on the first surface of the semiconductor chip die, and a redistribution pad arranged on the first surface of the semiconductor chip die and electrically connected to the connection pad and including an end portion having a concave-convex structure and extended to a lateral surface of the semiconductor chip die.

In example embodiments, the end portion may include a plurality of protrusions forming the concave-convex structure.

In example embodiments, a distance between the protrusions may be substantially from 1 μm to 10 μm.

According to example embodiments, a semiconductor package comprises a substrate including a substrate connection pad and a first semiconductor chip stacked on the substrate. The first semiconductor chip comprises a first semiconductor chip die having a first surface and a second surface opposite to the first surface, a first connection pad arranged on the first surface of the first semiconductor chip die, and a first redistribution pad arranged on the first surface of the first semiconductor chip die and electrically connected to the first connection pad, includes an end portion extending to a lateral surface of the first semiconductor chip die and having a concave-convex structure.

In example embodiments, the semiconductor package may further include a conductive line electrically connecting the substrate connection pad to the first redistribution pad

In example embodiments, the conductive line is on the lateral surface of the first semiconductor chip die and extends in a direction substantially perpendicular to the substrate.

In example embodiments, the end portion of the first redistribution pad comprises a plurality of protrusions forming the concave-convex structure.

In example embodiments, a distance between the protrusions range from about 1 μm to about 10 μm.

In example embodiments, the semiconductor package may further include a second semiconductor chip on the substrate and connected to the conductive line. The second semiconductor chip includes a second semiconductor chip die having a first surface and a second surface opposite to the first surface, a second connection pad on the first surface of the second semiconductor chip die, and a second redistribution pad on the first surface of the second semiconductor chip die and electrically connected to the second connection pad, and includes an end portion extending to a lateral surface of the second semiconductor chip die and having a concave-convex structure.

In example embodiments, the conductive line is arranged on the lateral surface of the second semiconductor chip die, and is connected to the second redistribution pad.

In example embodiments, a distance between the protrusions may be substantially from 1 μm to 10 μm.

According to example embodiments, in a method of manufacturing the semiconductor package, a wafer including a die region having a plurality of preliminary semiconductor chips and a cutting region is prepared. A plurality of preliminary redistribution pads are formed on the cutting region, the cutting region having a sectioning line along which the wafer is sectioned. The wafer and the preliminary redistribution pads are along the sectioning line using a laser to generate individual preliminary redistribution chips, and to form semiconductor chips including redistribution pads, one or more of the redistribution pads having an end portion having a concave-convex structure are cut. The semiconductor chips are stacked on a substrate having a substrate connection pad. Conductive lines electrically connecting the redistribution pads of the semiconductor chips to each other are formed.

In example embodiments, one or more of the plurality of preliminary redistribution pads comprise an end portion having the shape of a fork blade.

In example embodiments, one or more of the plurality of preliminary redistribution pads comprise an end portion having the shape of a triangular sectioning or sawing blade.

In example embodiments, one or more of the plurality of preliminary redistribution pads comprise a plurality of holes spaced apart from each other.

In example embodiments, the holes have a cross-sectional shape of one of a polygon, a circle, and an oval.

In example embodiments, the end portion of one or more of the plurality of redistribution pads includes a plurality of protrusions forming the concave-convex structure.

In example embodiments, a distance between the protrusions range from about 1 μm to about 10 μm.

In example embodiments, the conductive line is connected to the substrate connection pad and extends in a direction substantially perpendicular to the substrate.

Example embodiments relate to an semiconductor package including a substrate having a substrate connection pad, and a first semiconductor chip on the substrate, the first semiconductor chip having a first connection pad and a first redistribution pad on a surface thereof, a second semiconductor chip on the first semiconductor chip, the second semiconductor chip having a second connection pad and a second redistribution pad on a surface thereof, and a conductive line on a surface of the substrate, a lateral surface of the first semiconductor chip and a lateral surface of the second semiconductor chip, the conductive line being configured to electrically connect the substrate, the first semiconductor chip and the second semiconductor chip.

In example embodiments, at least one of the end portion of the first redistribution pad and the end portion of the second redistribution pad has a comb-like configuration.

### BRIEF DESCRIPTION OF THE DRAWINGS

Example embodiments will be more clearly understood from the following detailed description taken in conjunction with the accompanying drawings. FIGS. 1 to 16 represent non-limiting, example embodiments as described herein.

FIG. 1 is a cross-sectional view illustrating a semiconductor package in accordance with example embodiments;

FIG. 2 is a plan view illustrating a first semiconductor chip in FIG. 1;

FIG. 3 is a perspective view illustrating a portion of a semiconductor package in FIG. 1;

FIG. 4 is a plan view illustrating a wafer having semiconductor chips in accordance with example embodiments;

FIG. 5 is an enlarged view illustrating the A region in FIG. 4.

FIGS. 6 to 9 are plan views illustrating preliminary redistribution pads in accordance with example embodiments;

FIGS. 10 to 13 are cross-sectional views illustrating a method of manufacturing a semiconductor package in accordance with example embodiments;

FIGS. 14 and 15 are plan views illustrating a method of manufacturing a semiconductor package according to a comparative example; and

FIG. 16 is a cross-sectional view illustrating a method of manufacturing a semiconductor package according to a comparative example.

### DETAILED DESCRIPTION OF EXAMPLE EMBODIMENTS

Various example embodiments will be described more fully hereinafter with reference to the accompanying drawings, in which example embodiments are shown. Example embodiments may, however, be embodied in many different forms and should not be construed as limited to example embodiments set forth herein. Rather, these example embodiments are provided so that this disclosure will be thorough and complete, and will fully convey the scope of example embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items. Further, it will be understood that when a layer is referred to as being “under” another layer, it can be directly under or one or more intervening layers may also be present. In addition, it will also be understood that when a layer is referred to as being “between” two layers, it can be the only layer between the two layers, or one or more intervening layers may also be present.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

In the drawing figures, the dimensions of layers and regions may be exaggerated for clarity of illustration. Like reference numerals refer to like elements throughout. The same reference numbers indicate the same components throughout the specification.

Spatially relative terms, such as “beneath,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

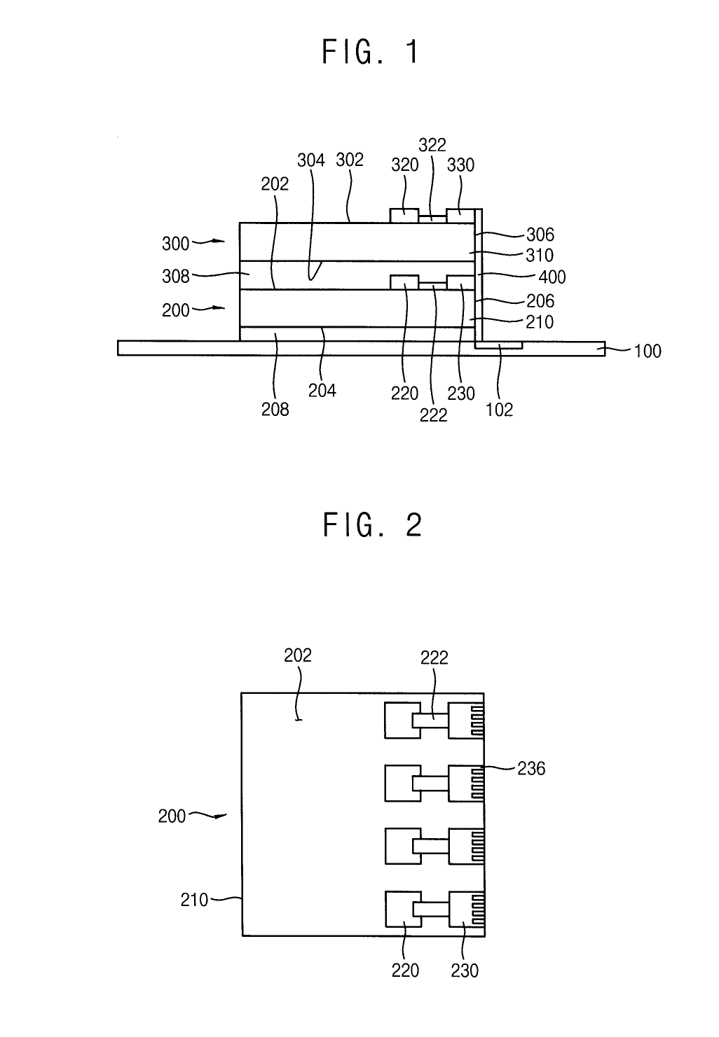

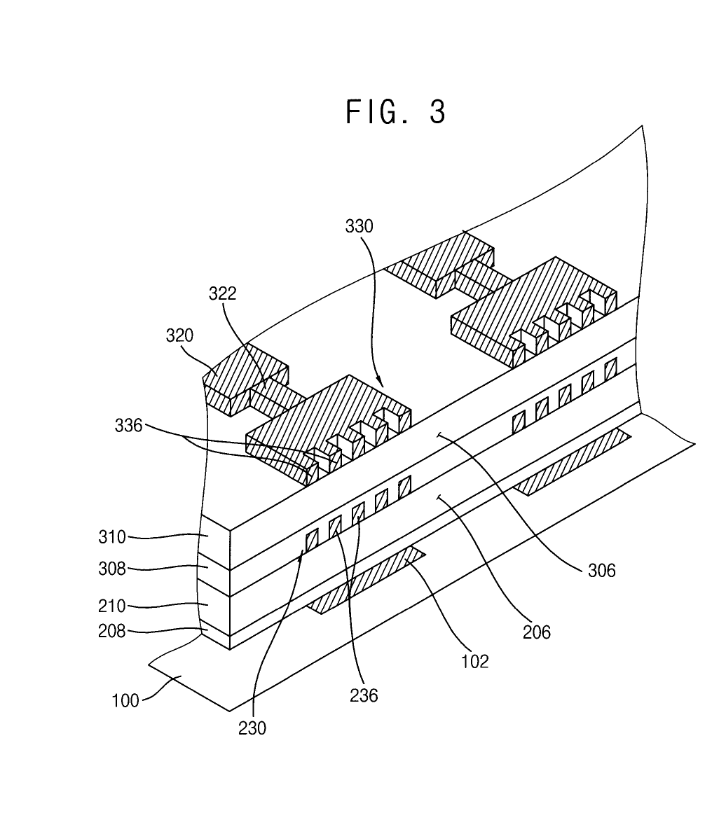

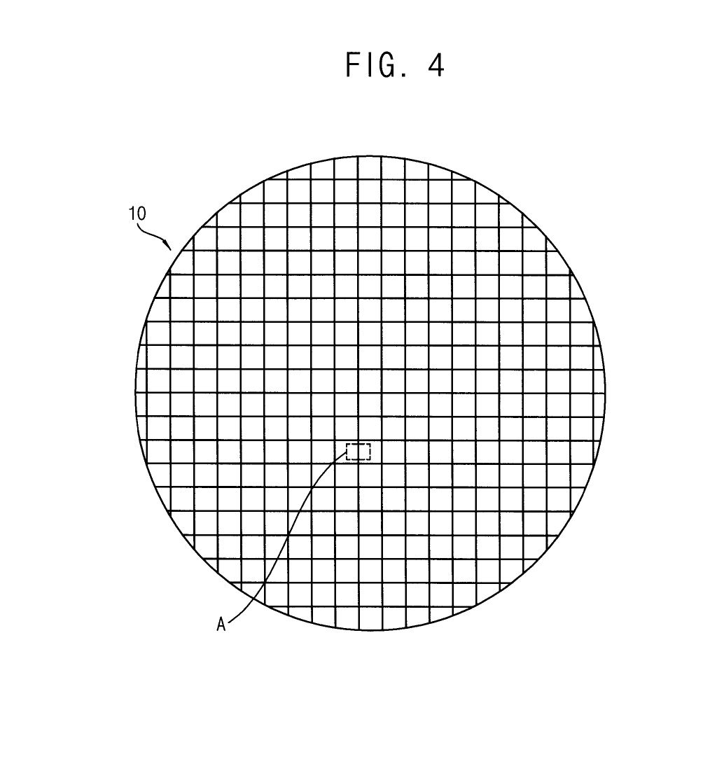

FIG. 1 is a cross-sectional view illustrating a semiconductor package in accordance with example embodiments. FIG. 2 is a plan view illustrating a first semiconductor chip in FIG. 1. FIG. 3 is a perspective view illustrating a portion of the semiconductor package in FIG. 1.

Referring to FIGS. 1 to 3, a semiconductor package may include a substrate 100 having a substrate connection pad 102, a first semiconductor chip 200 stacked on the substrate 100, and a second semiconductor chip 300 stacked on the first semiconductor chip 200.

In example embodiments, the substrate 100 may have an upper surface and a lower surface opposite to each other. For example, the substrate 100 may be a printed circuit board (PCB). The PCB may be a multi-layered circuit board having vias and various circuits therein.

The substrate connection pad 102 may be formed on the upper surface of the substrate 100, and an external connection pad (not illustrated) may be formed on the lower surface of the substrate 100. A plurality of the substrate connection pads 102 may be exposed by an insulation layer pattern (not illustrated) on the upper surface of the substrate 100.

The first semiconductor chip 200 may be mounted on the upper surface of the substrate 100. For example, the first semiconductor chip 200 may be adhered or attached to the upper surface of the substrate 100 by a first adhesive layer 208. The first adhesive layer 208 may be interposed between the first semiconductor chip 200 and the substrate 100 to adhere or attach the first semiconductor chip 200 to the substrate 100.

The second semiconductor chip 300 may be mounted on a first surface 202 of a first semiconductor chip die. For example, the second semiconductor chip 300 may be attached on the first surface 202 of the first semiconductor chip die 210 by a second adhesive layer 308. The second adhesive layer 308 may be interposed between the first semiconductor chip 200 and the second semiconductor chip 300 to adhere or attach the second semiconductor chip 300 to the first semiconductor chip 200.

As illustrated in FIG. 1, the semiconductor package may include two semiconductor chips 200 and 300, but the number of the stacked semiconductor chips may not be limited thereto. The first and second semiconductor chips 200 and 300 may include a plurality of circuit elements formed therein. The circuit element may include a plurality of memory elements. The memory element may be a volatile memory element or a non-volatile memory element. The volatile semiconductor memory element, for example, may be a DRAM or an SRAM. The non-volatile semiconductor memory element, for example, may be a Flash Memory, MRAM, PRAM, or ReRAM.

The first semiconductor chip 200 may include the first semiconductor chip die 210, a first connection pad 220, and a first redistribution pad 230. The first semiconductor chip die 210 may include the first surface 202 and a second surface 204 opposite to the first surface 202. The first connection pad 220 may be arranged on the first surface 202 of the first semiconductor chip die 210. The first redistribution pad 230 may be arranged on the first surface 202 of the first semiconductor chip die 210 and may be electrically connected to the first connection pad 220. The first connection pad 220 may be electrically connected to the circuit elements (not shown) included in the first semiconductor chip 200. The first connection pad 220 may include a conductive material. The first connection pad 220 may be connected to the first redistribution pad 230 via a first redistribution wiring 222 arranged on the first surface 202 of the first semiconductor chip die 210.

For example, as illustrated in FIG. 2, a plurality of the first connection pads 220 may be arranged adjacent to a side surface of the first semiconductor chip die 210. The first semiconductor chip 200 may include four first connection pads 220 along a side of the first semiconductor chip die 210, however, the number of the first connection pads 220 may not be limited thereto.

The first redistribution pad 230 may be extended to a lateral surface 206 of the first semiconductor chip die 210 and may include an end portion having a concave-convex structure. For example, the end portion may include a plurality of protrusions 236 exposed over the lateral surface 206 of the first semiconductor chip die 210. For example, the plurality of protrusions 236 may have a comb-like configuration. For example, a side surface of the protrusion 236 may be exposed to outside the first semiconductor chip die 210. For example, a distance between the protrusions 236 may range from about 1 μm to about 10 μm. The first redistribution pad 230 may include a conductive material. A plurality of the first redistribution pads 230 may be arranged along the side of the first semiconductor chip die 210. As illustrated in FIG. 2, the first semiconductor chip 200 may include four first redistribution pads 230 along the side of the first semiconductor chip die 210, however, the number of the first redistribution pads 220 may not be limited thereto.

The second semiconductor chip 300 may include a second semiconductor chip die 310, a second connection pad 320, and a second redistribution pad 330. The second semiconductor chip die 310 may include a first surface 302 and a second surface 304 opposite to the first surface 302. The second connection pad 320 may be arranged on the first surface 302 of the second semiconductor chip die 310. The second redistribution pad 330 may be arranged on the first surface 302 of the second semiconductor chip die 310 and may be electrically connected to the second connection pad 320. The second connection pad 320 may be electrically connected to the circuit elements (not shown) included in the second semiconductor chip 300. The second connection pad 320 may include a conductive material. A second redistribution wiring 322 may be arranged on the first surface 302 of the second semiconductor chip die 310 to electrically connect the second connection pad 320 to the second redistribution pad 330.

For example, similarly to the first connection pad 220, a plurality of the second connection pads 320 may be arranged adjacent to a side surface of the second semiconductor chip die 310.

The second redistribution pad 330 may be arranged on the first surface 302 of the second semiconductor chip die 310, and extend to a lateral surface 306 of the first semiconductor chip die 210 and may include an end portion having a concave-convex structure. For example, the end portion may include a plurality of protrusions 336 exposed over the lateral surface 306 of the second semiconductor chip die 310. For example, the plurality of protrusions 336 may have a comb-like configuration. For example, a side surface of the protrusion 336 may be exposed to outside the second semiconductor chip die 310. For example, a distance between the protrusions 336 may range from about 1 μm to about 10 μm. The second redistribution pad 330 may include a conductive material.

A plurality of the second redistribution pads 330 may be arranged along the side of the second semiconductor chip die 310.

In example embodiments, the semiconductor package may further include a conductive line 400 that electrically connects the substrate connection pad 102, formed on the upper surface of the substrate 100, with the first and second redistribution pads 230 and 330. The conductive line 400 may be connected to the substrate connection pad 102, and may extend in a direction substantially perpendicular to the substrate 100, or in a direction parallel to a stacking direction of the substrate 100, the first semiconductor chip 200 and the second semiconductor chip 300, to contact the first and second redistribution pads 230 and 330. For example, the conductive line 400 may extend on the lateral surfaces 206 and 306 of the first and second semiconductor chip dies 210 and 310, may contact the protrusions 236 and 336 of the first and second redistribution pads 230 and 330, which are exposed to the lateral surfaces of the first and second semiconductor chip dies 210 and 310, and may be connected to the substrate connection pad 102.

The conductive line 400 may be a pathway of a signal or power required for operations of the first and second semiconductor chips 200 and 300. The signal may be a data signal or a control signal. For example, the control signal may include a command signal or a clock signal. The power may include a power voltage and a ground voltage. Therefore, the signal and the power may be supplied to the first and second semiconductor chips 200 and 300 via the conductive line 400.

The semiconductor package in accordance with example embodiments may include the first and second redistribution pads 230 and 330 including an end portion having a concave-convex structure. The end portions of the first and second redistribution pads 230 and 330 are exposed over the lateral surfaces 206 and 306 of the first and second semiconductor chip dies 210 and 310 respectively. Therefore, the substrate 100 may be electrically connected to the first semiconductor chip 200, and the second semiconductor chip 300 via the conductive line 400, thereby improving an operational reliability of the semiconductor package while avoiding or reducing the possibility of a poor electrical connection.

Hereinafter, a method of manufacturing the semiconductor package in FIG. 1 is explained in detail.

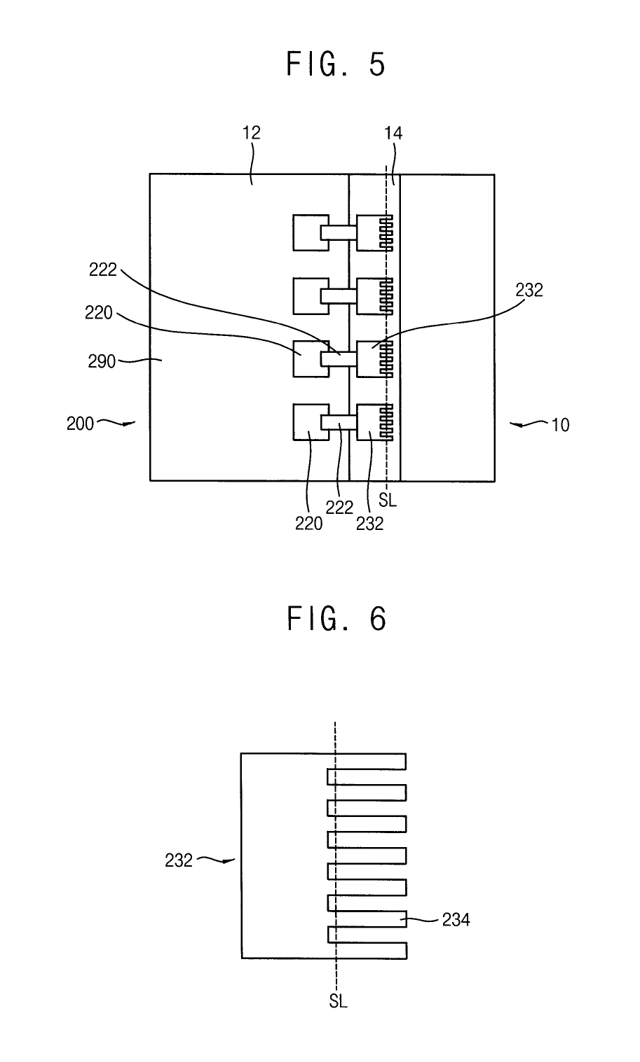

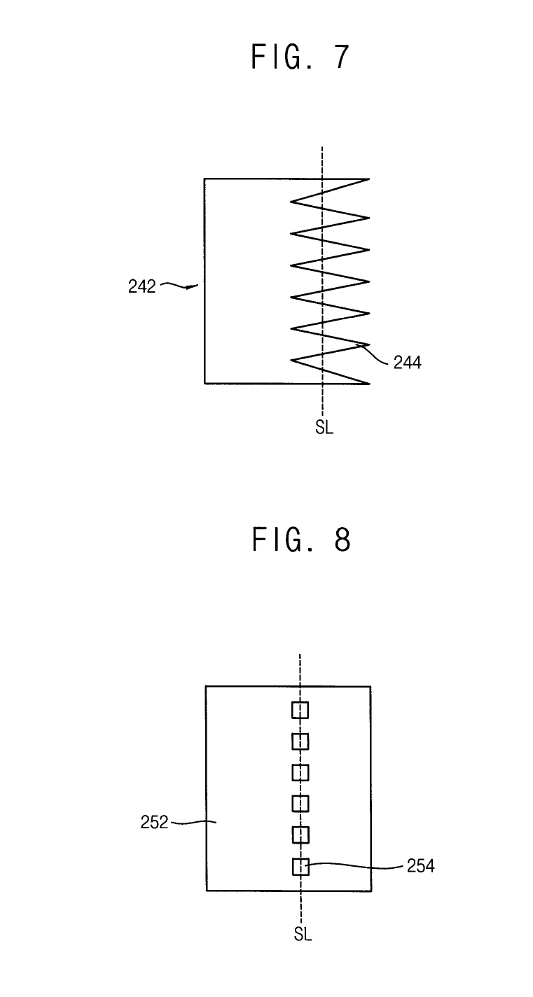

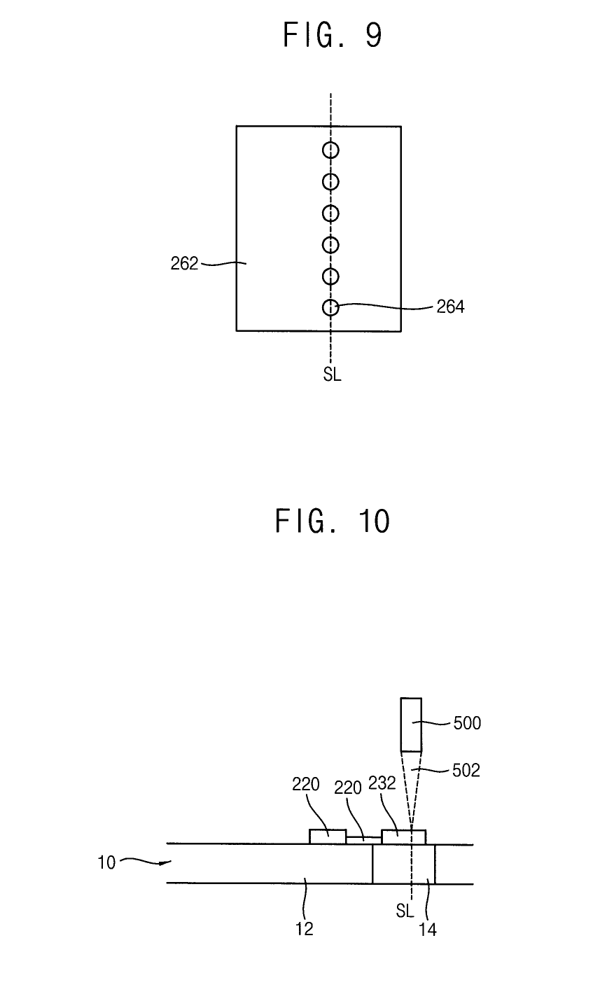

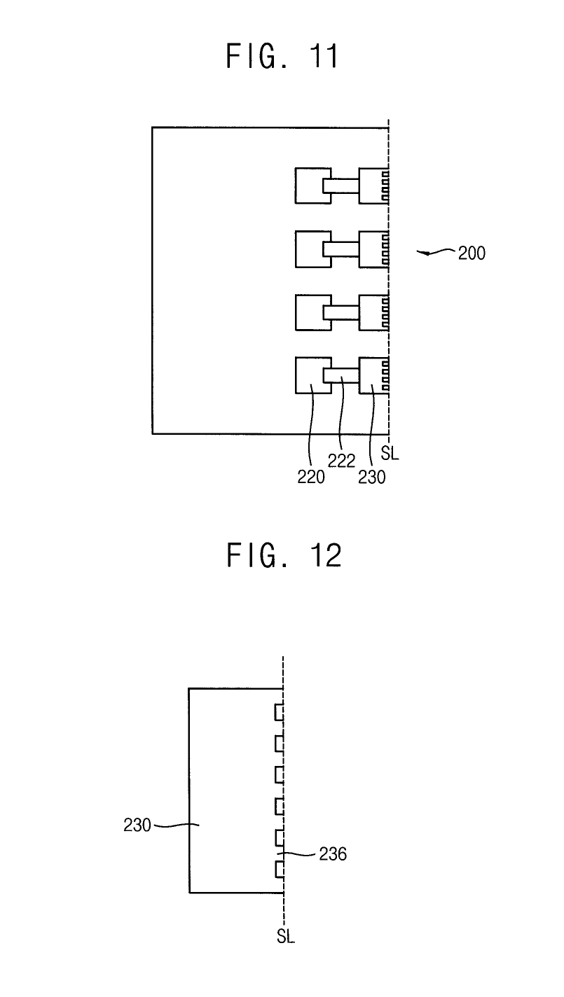

FIG. 4 is a plan view illustrating a wafer having semiconductor chips in accordance with example embodiments. FIG. 5 is an enlarged view illustrating the region labeled “A” in FIG. 4. FIGS. 6 to 9 are plan views illustrating preliminary redistribution pads in accordance with example embodiments. FIGS. 10 to 13 are cross-sectional views illustrating a method of manufacturing a semiconductor package in accordance with example embodiments.

Referring to FIGS. 4 and 5, a wafer 10 including a plurality of semiconductor chips may be provided. A plurality of preliminary redistribution pads 232 may be formed on the wafer 10 along a sectioning line SL along which the wafer 10 is sectioned into the individual semiconductor chips.

In example embodiments, the wafer 10 may include a die region 12 and a cutting region 14. Preliminary semiconductor chips 290 may be formed on the die regions 12 respectively. That is, the preliminary semiconductor chips 290 may be divided by the cutting region 14. The cutting region 14 may be cut by a sectioning process such as, for example, sawing. For example, the sectioning line SL may be located on the cutting region 14.

In example embodiments, as illustrated in FIG. 5, first connection pads 220 may be formed on the die region 12, and the preliminary redistribution pads 232 may be formed on the cutting region 14. First redistribution wirings 222 may be formed to extend from the die region 12 to the cutting region 14 to connecting the preliminary redistribution pads 232 to the first connection pads 220. For example, the preliminary redistribution pads 232, the first connection pads 220, and the first redistribution wirings 222 may be formed by an electro-plating process or an electroless plating process.

The preliminary redistribution pads 232, for example, as illustrated in FIG. 6, may include a plurality of end portions 234, one or more of which having the shape of a fork blade.

As illustrated in FIG. 7, preliminary redistribution pads 242 may include end portions 244, one or more of which having the shape of a triangular saw blade.

Alternatively, as illustrated in FIGS. 8 and 9, preliminary redistribution pads 252 and 262 may include a plurality of holes 254 and 264, respectively, being spaced apart from each other. The holes 254 may have a shape of polygon, and the holes 264 may have a shape of circle or oval, for example.

According to at least one example embodiment, the wafer 10 may be cut along the sectioning line SL, as illustrated in FIGS. 5 to 9. For example, as illustrated in FIG. 10, the wafer 10 may be cut via a laser sectioning process to be divided into the individual preliminary semiconductor chips 290, to form the semiconductor chip 200 in FIG. 11. During the laser sectioning process, portions of the preliminary redistribution pads 232 of the preliminary semiconductor chips 290 may be removed. Therefore, a cutting end portion having a concave-convex structure, e.g., the redistribution pads 230 of the semiconductor chip 200 illustrated in FIG. 12, may be formed. For example, as illustrated in FIG. 12, the redistribution pads 230 may include a plurality of protrusions 236, and a distance between the protrusions 236 may range from about 1 μm to about 10 μm.

For example and as illustrated in FIG. 10, during the laser sectioning process, a laser beam 502 generated from a laser source 500 may be irradiated onto the wafer 10 (in particular, onto the cutting region 14 on the wafer 10) along the sectioning line SL, to section off a portion of one or more the preliminary redistribution pads 232. In example embodiments, after the wafer is exposed to the laser beam 502, a mechanical stress may be applied to the wafer 10 to section off the preliminary semiconductor chips 290.

Referring to FIG. 13, the semiconductor chips 200 and 300 divided by the laser sectioning process may be sequentially stacked on the substrate 100 including the substrate connection pad 102 formed thereon. The semiconductor chips 200 and 300 may include the first and second redistribution pads 230 and 330 including the protrusions 236 and 336 illustrated in FIG. 3. The semiconductor chips 200 and 300 may be mounted on the substrate 100 using the adhesive layers 208 and 308. The conductive line 400 may be formed on the substrate 100 to electrically connect the semiconductor chips 200 and 300 to the substrate connection pad 102 of the substrate 100. The conductive line 400 may be formed on a side surface of the semiconductor chips 200 and 300 and may extend in a direction substantially perpendicular to the substrate 100, or in a direction substantially parallel to a stacking direction of the substrate 100, the first semiconductor chip 200 and the second semiconductor chips 300. The conductive line 400 may make contact with the redistribution pads 230 of the semiconductor chips 200 and 300. For example, the conductive line 400 may make contact with the protrusions 236 and 336 illustrated in FIG. 3 of the redistribution pads 230 and 330 of the semiconductor chips 200 and 300.

Hereinafter, a conventional method of manufacturing a semiconductor package will be explained.

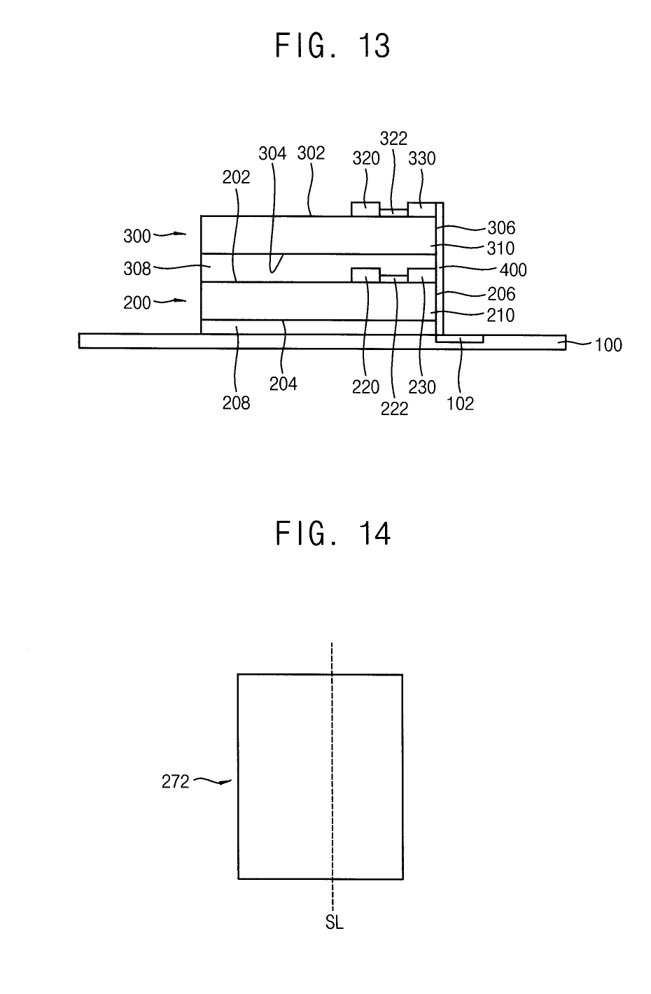

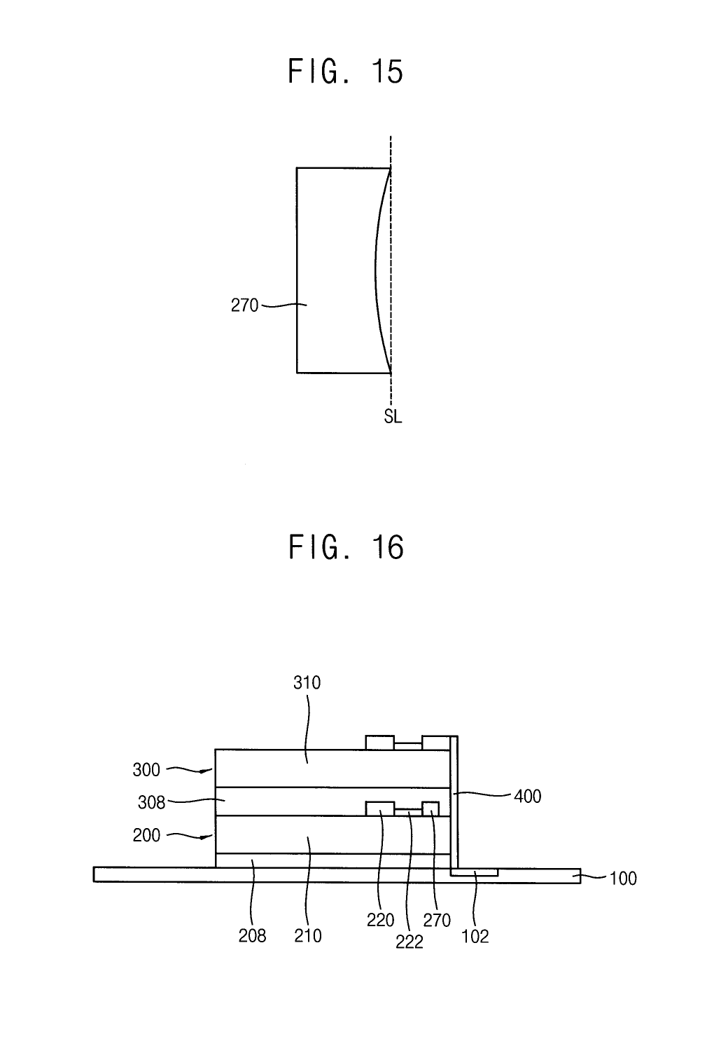

FIGS. 14 and 15 are plan views illustrating a conventional method of manufacturing a semiconductor package, herein provided as a comparative example. FIG. 16 is a cross-sectional view illustrating a conventional method of manufacturing a semiconductor package, herein provided as a comparative example.

Referring to FIGS. 14 and 15, a laser beam may be irradiated on a conventional preliminary redistribution pad 272 along a sectioning line SL and a mechanical stress may be applied to the wafer to at least partially remove the preliminary redistribution pad 272, to form a redistribution pad.

When the mechanical stress is applied to the wafer to remove a portion of the preliminary redistribution pad 272 in order to form the redistribution pad 270, as illustrated in FIG. 15, the portion of the preliminary redistribution pad 272 may not be removed accurately along the sectioning line SL, and an inner portion the redistribution pad 270, that is distinct from the sectioning line SL, may also be unintentionally removed.

Referring to FIG. 16, the conductive line 400 and the redistribution pad 270 may be spaced apart from each other as a result of the fact that an inner portion of the redistribution pad 270 is at least partially removed. Accordingly, the conductive line 400 and the redistribution pad 270 may not be electrically connected, causing a connection failure.

According to example embodiments, a preliminary redistribution pad including an end portion with a fork shape or holes may be used to form the redistribution pad. When the wafer is cut along the sectioning line by a sectioning process to separate the semiconductor chips, the preliminary redistribution pad may be precisely removed, thereby reducing the possibility of a failure of the redistribution pad during the sectioning process and avoiding having an inner portion of the redistribution pad unintentionally removed as well.

Particularly, the electrical connection reliability between the substrate connection pad and the redistribution pad may be improved because the redistribution pad may be formed to include an end portion having a concave-convex structure.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A semiconductor package, comprising:
a substrate including a substrate connection pad; and
a first semiconductor chip on the substrate, the first semiconductor chip including,
a first semiconductor chip die having a first surface and a second surface opposite to the first surface;
a first connection pad on the first surface of the first semiconductor chip die; and
a first redistribution pad on the first surface of the first semiconductor chip die and electrically connected to the first connection pad, the first redistribution pad including an end portion extending to a lateral surface of the first semiconductor chip die and having a concave-convex structure.

2. The semiconductor package of claim 1, further comprising:
a conductive line electrically connecting the substrate connection pad to the first redistribution pad.

3. The semiconductor package of claim 2, wherein the conductive line is on the lateral surface of the first semiconductor chip die and extends in a direction substantially perpendicular to the substrate.

4. The semiconductor package of claim 1, wherein the end portion of the first redistribution pad comprises a plurality of protrusions forming the concave-convex structure.

5. The semiconductor package of claim 4, wherein a distance between the protrusions range from about 1 μm to about 10 μm.

6. The semiconductor package of claim 2, further comprising:
a second semiconductor chip on the substrate and connected to the conductive line,
the second semiconductor chip including,
a second semiconductor chip die having a first surface and a second surface opposite to the first surface;
a second connection pad on the first surface of the second semiconductor chip die; and
a second redistribution pad on the first surface of the second semiconductor chip die and electrically connected to the second connection pad, the second redistribution pad including an end portion extending to a lateral surface of the second semiconductor chip die and having a concave-convex structure.

7. The semiconductor package of claim 6, wherein the conductive line is on the lateral surface of the second semiconductor chip die, and is connected to the second redistribution pad.

8. A method of manufacturing a semiconductor package, comprising:
preparing a wafer including a die region and a cutting region, the die region having a plurality of preliminary semiconductor chips;
forming a plurality of preliminary redistribution pads on the cutting region, the cutting region having a sectioning line along which the wafer is sectioned;
sectioning the wafer and the preliminary redistribution pads along the sectioning line using a laser to generate individual preliminary redistribution chips and to form semiconductor chips including redistribution pads, one or more of the redistribution pads having an end portion having a concave-convex structure;
stacking the semiconductor chips on a substrate having a substrate connection pad; and
forming a conductive line electrically connecting the redistribution pads of the semiconductor chips to each other.

9. The method of claim 8, wherein one or more of the plurality of preliminary redistribution pads comprise an end portion having a shape of a fork blade.

10. The method of claim 8, wherein one or more of the plurality of preliminary redistribution pads comprise an end portion having a shape of a triangular saw blade.

11. The method of claim 8, wherein one or more of the plurality of preliminary redistribution pads comprise a plurality of holes spaced apart from each other.

12. The method of claim 11, wherein the holes have a cross-sectional shape of one of a polygon, a circle, and an oval.

13. The method of claim 8, wherein the end portion of one or more of the plurality of redistribution pads includes a plurality of protrusions forming the concave-convex structure.

14. The method of claim 13, wherein a distance between the protrusions range from about 1 μm to about 10 μm.

15. The method of claim 8, wherein the conductive line is connected to the substrate connection pad and extends in a direction substantially perpendicular to the substrate.

16. A semiconductor package, comprising:
a substrate including a substrate connection pad;
a first semiconductor chip on the substrate, the first semiconductor chip having a first connection pad and a first redistribution pad on a surface thereof;
a second semiconductor chip on the first semiconductor chip, the second semiconductor chip having a second connection pad and a second redistribution pad on a surface thereof; and
a conductive line on a surface of the substrate, a lateral surface of the first semiconductor chip and a lateral surface of the second semiconductor chip, the conductive line being configured to electrically connect the substrate, the first semiconductor chip and the second semiconductor chip.

17. The semiconductor package of claim 16, wherein
the first connection pad is electrically coupled to the first redistribution pad; and
the first redistribution pad includes an end portion extending to the lateral surface of the first semiconductor chip.

18. The semiconductor package of claim 17, wherein
the second connection pad is electrically coupled to the second redistribution pad; and
the second redistribution pad includes an end portion extending to the lateral surface of the second semiconductor chip.

19. The semiconductor package of claim 18, wherein at least one of the end portion of the first redistribution pad and the end portion of the second redistribution pad has a concave-convex configuration.

20. The semiconductor package of claim 18, wherein at least one of the end portion of the first redistribution pad and the end portion of the second redistribution pad has a comb-like configuration.
